(19) United States
(12) Patent Application Publication
(10) Pub. No.: US 2026/0324012 A1
(43) Pub. Date: Oct. 15, 2026

(54) INTERFACES FOR INHIBITING MOISTURE MIGRATION FOR SEMICONDUCTOR DEVICES

(71) Applicant: Microchip Technology Incorporated, Chandler, AZ (US)

(72) Inventors: Shesh Pandey, Gilbert, AZ (US); George Dorman, Chandler, AZ (US); Yogesh Sharma, Colorado Springs, CO (US)

(73) Assignee: Microchip Technology Incorporated, Chandler, AZ (US)

(21) Appl. No.: 19/252,866

(22) Filed: Jun. 27, 2025

Related U.S. Application Data
(60) Provisional application No. 63/788,482, filed on Apr. 14, 2025.

(51) Int. Cl. H10D 62/10

(52) U.S. Cl. CPC H10D 62/107; H10D 62/126

(57) ABSTRACT

A semiconductor device comprising a substrate having a first type dopant; an active region; a termination region laterally adjacent to the active region, the termination region comprising a plurality of doped channels in the substrate, the plurality of doped channels having a second type dopant; and a trench in the substrate, wherein the trench is laterally between two of the plurality of doped channels, wherein the trench is filled with a dielectric material; and a dielectric layer on the plurality of doped channels and the trench.

### CROSS-REFERENCE TO RELATED APPLICATION

This application claims the benefit of U.S. Provisional Patent Application No. 63/788,482, filed Apr. 14, 2025.

### TECHNICAL FIELD

The present disclosure relates generally to semiconductor devices, and more specifically to interfaces for inhibiting moisture migration for semiconductor devices.

### BACKGROUND

A power semiconductor device is an electronic component to efficiently and reliably control and convert electrical power at relatively high voltages and currents. Unlike regular signal-level semiconductors used in low-power applications, in some instances power semiconductor devices may be optimized for switching and amplifying large amounts of energy. Power semiconductor devices may be used in a variety of applications, such as motor drives, power supplies, renewable energy systems, electric vehicles, and the like.

A power semiconductor device may generate a high electric field which may promote moisture migration towards the active area of the semiconductor device. Moisture-induced degradation mechanisms such as corrosion, electrochemical migration, and dielectric breakdown may lead to device failure. A device's susceptibility to moisture migration may be tested using a high humidity high temperature reverse bias (H3TRB) test. During H3TRB testing, the device is subjected to high humidity (e.g., 85% relative humidity), elevated temperature (e.g., 85 °C), and a reverse bias voltage for an extended period (e.g., 1000 hours) to evaluate the device's ability to maintain performance and reliability in humid and high-temperature applications.

### SUMMARY OF THE INVENTION

Aspects provide interfaces for inhibiting moisture migration for semiconductor devices.

In one aspect, a semiconductor device comprises a substrate having a first type dopant; an active region; a termination region laterally adjacent to the active region, the termination region comprising a plurality of doped channels in the substrate, the plurality of doped channels having a second type dopant; and a trench in the substrate, wherein the trench is laterally between two of the plurality of doped channels, wherein the trench is filled with a dielectric material; and a dielectric layer on the plurality of doped channels and the trench.

In another aspect, a method comprises forming an active region in a substrate having a first type dopant; forming a termination region laterally adjacent to the active region, the termination region comprising a plurality of doped channels in the substrate, the plurality of doped channels having a second type dopant; and a trench in the substrate, wherein the trench is laterally between two of the plurality of doped channels, wherein the trench is filled with a dielectric material; and forming a dielectric layer on the plurality of doped channels and the trench.

In yet another aspect, an apparatus comprises a semiconductor device package comprising a die comprising a substrate having a first type dopant; a plurality of doped channels in the substrate, the plurality of doped channels having a second type dopant, the plurality of doped channels to reduce an electric field from an active region of the die; a trench in the substrate, wherein the trench is laterally between two of the plurality of doped channels, wherein the trench is filled with a dielectric material; and a dielectric layer on the plurality of doped channels and the trench.

### BRIEF DESCRIPTION OF THE DRAWINGS

FIG. 1 illustrates a portion of a die comprising a semiconductor device, the die comprising barrier interfaces in a die seal region to inhibit moisture migration, in accordance with any of the examples disclosed herein.

FIG. 2 illustrates a horizontal cross section of the die of FIG. 1, in accordance with any of the examples disclosed herein.

FIG. 3 illustrates a flow for manufacturing barrier interfaces in a die seal region to inhibit moisture migration, in accordance with any of the examples disclosed herein.

FIG. 4 illustrates an alternative flow for manufacturing barrier interfaces in a die seal region to inhibit moisture migration, in accordance with any of the examples disclosed herein.

FIG. 5 illustrates a portion of a die comprising a semiconductor device, the die comprising barrier interfaces in a termination region to inhibit moisture migration, in accordance with any of the examples disclosed herein.

FIG. 6 illustrates a portion of a die comprising a semiconductor device, the die comprising barrier interfaces in a die seal region and barrier interfaces in a termination region to inhibit moisture migration, in accordance with any of the examples disclosed herein.

FIG. 7 illustrates a horizontal cross section of the die of FIG. 6, in accordance with any of the examples disclosed herein.

FIG. 8 illustrates a flow for manufacturing barrier interfaces in a die seal region and barrier interfaces in a termination region to inhibit moisture migration, in accordance with any of the examples disclosed herein.

### DETAILED DESCRIPTION

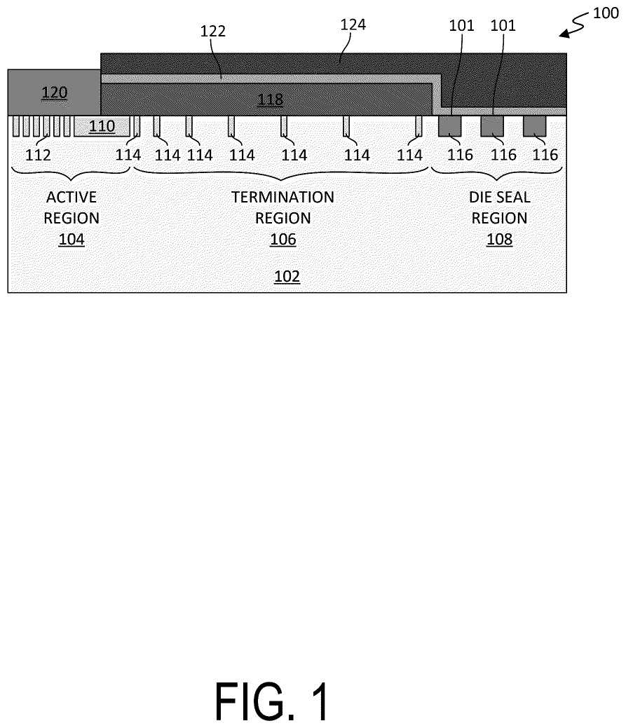

FIG. 1 illustrates a portion (e.g., an outer edge) of a die 100 comprising a semiconductor device, the die comprising barrier interfaces 101 in a die seal region 108 to inhibit moisture migration, in accordance with any of the examples disclosed herein. As depicted, the die 100 includes a substrate 102 and various layers formed in and over the substrate. The substrate may comprise a semiconductor material, e.g., silicon, silicon carbide, or other suitable semiconductor material. The die 100 may include an active region 104, a termination region 106, and a die seal region 108.

As will be described in further detail below, the die 100 may be susceptible to moisture migration through the interface between the substrate 102 and one or more dielectric layers (e.g., dielectric layer 118 or dielectric layer 122). The moisture migration may harm the circuitry in the active region 104. Various examples of the present disclosure may inhibit moisture migration through the addition of one or more barrier channels that interface with one or more dielectric layers (e.g., dielectric layer 118 or dielectric layer 122). Thus, moisture will travel more slowly through the die seal region 108 or termination region 106 more slowly relative to a die 100 that does not utilize barrier channels.

In various examples, die 100 includes one or more semiconductor devices. In some instances, die 100 may include one or more power semiconductor devices. A power semiconductor device may include any suitable semiconductor device that can accommodate high voltage (e.g., between 10V-8000V, but not limited thereto) applied to one or more terminals or high current (e.g., between 5 A-1000 A, but not limited thereto) flowing through one or more terminals. As examples, a power semiconductor device may comprise a metal-oxide-semiconductor field-effect transistor (MOSFET), a junction field-effect transistor (JFET), an insulated gate bipolar transistor (IGBT), a bipolar junction transistor (BJT), a thyristor, a diode, or the like. In some examples, the die 100 includes a single discrete semiconductor power device. In other examples, the die 100 includes a plurality of semiconductor power devices (e.g., a pair of power semiconductors, such as a field-effect transistor (FET) coupled to a diode).

The active region 104 may include the portion of die 100 where electrical conduction and switching occur. The die 100 may comprise various regions of doped semiconductor materials (e.g., n-type and p-type) that form the junctions responsible for the behavior of the semiconductor device(s) of the die 100. For example, in a MOSFET, the active region contains the channel between source and drain, where the electric field controls current flow. As another example, in an IGBT, the active area includes both the MOS-gated structure and the PN junction that handles high voltages.

In the example depicted, the portion of the active region 104 that is shown includes an implant 110 (e.g., used for isolation purposes, such as the isolation of the implant rings 112 and the guard channels 114) and implant rings 112 (which may be, e.g., part of the intrinsic device structure such as the P+ body contact) as well as a metal layer 120 (which may be a source terminal of a MOSFET as one example). At its edge, the active region 104 may also include small portions of dielectric layers 118, 122, and 124.

Power semiconductor devices include one or more p-n junctions in the active region 104 between a p-type semiconductor and an n-type semiconductor. These junctions in the active region 104 may emit an electric field in a lateral direction. This electric field may increase the susceptibility of the die to moisture migration through the die seal region 108 towards the active region 104.

To reduce the electric field emitted in the lateral direction, guard channels 114 may be formed in a termination region 106 of the substrate 102 of the die 100. In some examples, the guard channels 114 may be rings (e.g., concentric rings) around the active region. In an example, the guard channels 114 may comprise substantially square shaped rings around the active region. In other examples, the guard channels 114 may have other suitable shapes or one or more discontinuities.

In various examples, the substrate 102 may include a semiconductor of a first dopant type (e.g., an n-type or p-type), while the termination region 106 includes a plurality of guard channels 114 of a second type (e.g., a p-type or n-type) formed laterally adjacent to the active region 104. The guard channels 114 may reduce the electric field that is emitted laterally from the active region 104 (e.g., through a widening of the depletion region). The guard channels 114 may include wells in the substrate 102 formed by implantation of an impurity (comprising, e.g., aluminum for a p-type guard channel). Various examples are provided below based on a first dopant type substrate (n-type substrate) with guard channels with a second dopant type (p-type guard channels), but in other examples, a p-type substrate with n-type guard channels may be utilized in the termination region 106. The magnitude of the electric field may decrease as the distance from the active region 104 increases in the lateral direction and is ideally zero at the outer edge of the termination region (the edge furthers from the active region 104). The number of guard channels 114 used may be dependent on the voltage of the device (e.g., higher voltage devices may include a larger number of guard channels).

In the example depicted, individual guard channels 114 have substantially the same width, but the width of separation between pairs of adjacent guard channels 114 monotonically increases as the distance from the active region 104 increases. In other examples, the guard channels 114 could have varying widths (or some may have the same width while others have different widths) or could be spaced differently (e.g., the distance between adjacent pairs of guard channels may be constant instead of monotonically increasing or the distance between some pairs may be a first magnitude while the distance between other pairs may be a second magnitude).

In various examples, the implant 110, implant rings 112, and guard channels 114 have substantially the same concentration of dopants. In other examples, the dopant concentration could be varied among implant 110, implant rings 112, or guard channels 114 (or among individual ones of implant 110, implant rings 112, or guard channels 114).

The die 100 may also include a variety of dielectric layers near the edge of the die to protect the semiconductor device(s) on the die. For example, the dielectric layers may protect the semiconductor device(s) against, e.g., stress, temperature, and humidity.

In the example depicted, dielectric layer 118 is formed over (e.g., on) the substrate 102 and the guard channels 114. In this example, the dielectric layer 118 spans in a lateral direction from the active region (e.g., over the implant 110) past the outermost guard channel 114 to the die seal region 108. The dielectric layer 118 may span from the edge of the active region through the termination region. In various examples, the dielectric layer 118 comprises oxygen and nitrogen. In an example, the dielectric layer comprises oxynitride.

Dielectric layer 122 is formed over (e.g., on) the dielectric layer 118 and the substrate 102. The dielectric layer 122 may extend laterally over the dielectric layer 118 within the termination region (past the outermost guard channel 114) and then descend vertically down to the substrate at the edge of the die seal region 108 and then extend laterally across the die seal region. In some examples, the thickness of the dielectric layer 122 may be substantially the same in the portion that extends laterally over the termination region 106 and in the portion that extends laterally over the die seal region. Dielectric layer 122 may comprise at least one of nitrogen, silicon, and oxygen. For example, dielectric layer 122 may comprise a nitride (e.g., silicon nitride) or an oxynitride (e.g., silicon oxynitride).

Dielectric layer 124 is formed over the dielectric layer 118, over the substrate 102, and over (e.g., on) the dielectric layer 122 within the termination region 106 and the die seal region 108. Although not shown, the dielectric layer 124 may also be formed over portions of the active region 104 (e.g., with openings formed for access to contact pads of the semiconductor device(s)). The dielectric layer 124 may be formed over the die seal region 108, Dielectric layer 124 may comprise, e.g., polyimide.

The die seal region 108 may be at the edge of the die 100. The various dielectric layers 118, 122, or 124 may present barriers to the outside environment. Within the die seal region 108, if the interface between the dielectric layer 122 and the substrate 102 is consistent along its length, excessive moisture could propagate along this interface (especially in high humidity environments) and then along the interface between the substrate 102 and the dielectric layer 118 in the termination region towards the active region, which may be detrimental to the operation of the die 100.

Various examples of the present disclosure may provide barrier interfaces (e.g., 101) for inhibiting moisture migration for semiconductor devices. In the example depicted in FIG. 1, trenches are formed (e.g., etched) in the substrate 102 within the die seal region 108. These trenches are then filled (e.g., via deposition) with a dielectric material to form barrier channels 116. The dielectric material may comprise one or more of silicon, oxygen, or nitrogen. For example, the dielectric material may comprise an oxide (e.g., silicon oxide, silicon dioxide) or a nitride.

Formation of the barrier channels 116 creates a different type of interface (e.g., barrier interface 101, where the dielectric material of a barrier channel 116 contacts the dielectric layer 122) in the die seal region that has an improved ability to inhibit propagation of moisture towards the active region 104. Thus, moisture will travel more slowly through the die seal region relative to a die seal region that includes a single barrier interface between the dielectric layer 122 and the substrate 102. In other examples, as an alternative (or in addition to one or more barrier channels 116), one or more barrier channels may be formed within the termination region 106 (e.g., between guard channels 114) and may provide an additional barrier interface between these barrier channels and the dielectric layer 118 to inhibit moisture migration towards the active region 104.

In the example depicted in FIG. 1, the die seal region 108 includes three barrier channels 116 with respective barrier interfaces 101 between the barrier channels 116 and dielectric layer 122. In other examples, the die seal region 108 could include additional barrier channels 116 or fewer barrier channels (including a single barrier channel 116 in some examples). When a plurality of barrier channels 116 are present, individual barrier channels 116 be the same width or depth, or may have different widths or depths. Similarly, the spacing between adjacent pairs of barrier channels 116 may be constant across all barrier channels or may vary. In one example, the spacing between adjacent pairs of barrier channels 116 increases with the distance from the active region. In another example, the spacing between adjacent pairs of barrier channels 116 decreases with the distance from the active region.

In some examples, the barrier channels 116 may all be outside of (e.g., further from the active region 104 than) the outermost guard channel 114 that is furthest from the active region 104. In the example depicted, the innermost barrier channel 116 slightly overlaps with the portion of the dielectric layer 122 that vertically descends down to the substrate 102 (on the side of the dielectric layer 118). In other examples, the one or more barrier channels 116 may be lateral to (e.g., outside of) and not overlap with the portion of the dielectric layer 122 that vertically descends to the substrate.

In various examples, one or more dielectric layers may be formed above the barrier interfaces 101. For example, in the example depicted, dielectric layer 124 is formed above the barrier interfaces 101.

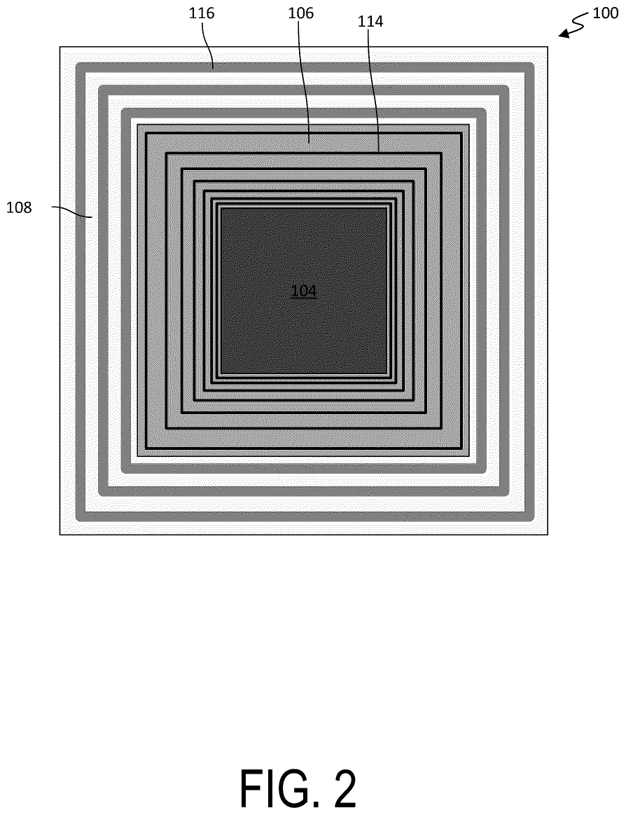

FIG. 2 illustrates a horizontal cross section of the die 100 of FIG. 1, in accordance with any of the examples disclosed herein. This horizontal cross section depicted may be through the die 100 at an elevation that passes through the guard channels 114 and barrier channels 116. As depicted, the die 100 is shaped as a square, but could have a different shape, such as substantially rectangular or other suitable shape. Similarly, the active region 104, termination region 106, and die seal region 108 are shown as squares, but may each have any suitable shape. FIG. 2 is not necessarily drawn to scale. For example, in various examples, the active region 104 may be wider than the combined width of the termination region 106 and the die seal region 108.

In the example depicted, the center of the die 100 includes the active region 104. The termination region 106 surrounds the active region 104, and the die seal region 108 surrounds the termination region 106. In this example, both the guard channels 114 and the barrier channels 116 comprise continuous rings around the active region 104. In this example, the rings have a generally rectangular shape, but may have other suitable shapes in other examples. In this example, the rings are concentric around the active region. For example, the guard channels 114 are concentric around the active region 104 and the barrier channels 116 are concentric around the active region and the termination region 106 (including the guard channels 114). In this example, the plurality of guard channels 114 comprise a plurality of concentric rings, spaced at increasing radial distances from the active region. In other examples, the rings may have one or more discontinuities (but may substantially form a ring). In yet other examples, the guard channels or barrier channels do not form rings, but are discrete channels (e.g., having a horizontal cross section of a line) near the edge of the die.

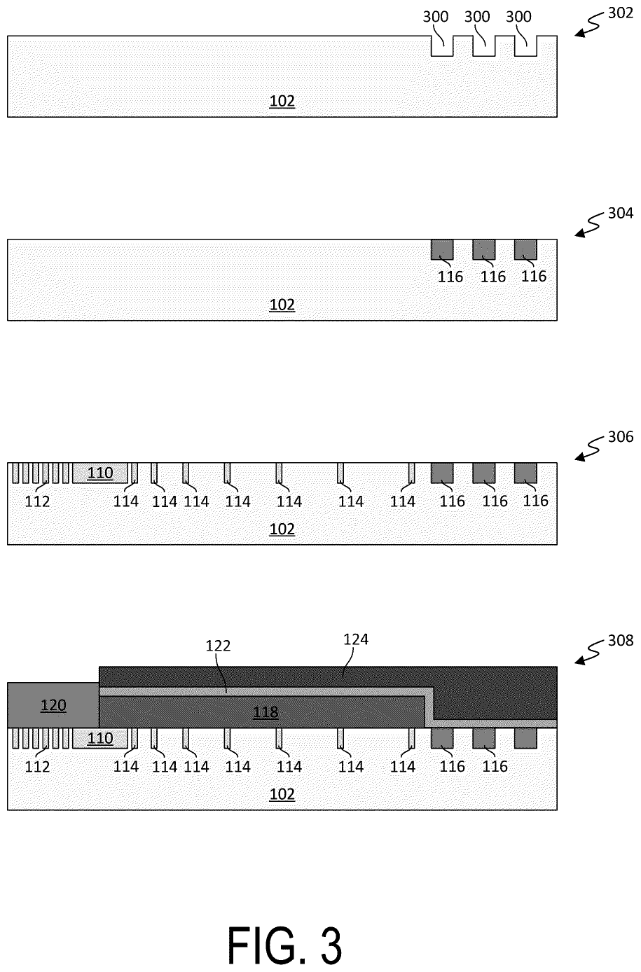

FIG. 3 illustrates a flow for manufacturing barrier interfaces in a die seal region to inhibit moisture migration, in accordance with any of the examples disclosed herein.

At 302, trenches 300 are formed in substrate 102 by removing material of the substrate. For example, the trenches 300 may be formed via application of a mask and a subsequent etch process. In some instances, the operation used to remove the material to form the trenches 300 may also be used to form other components of the die 100. For example, in a trench MOSFET process, a trench for a gate of a MOSFET may be formed concurrently with trenches 300 (e.g., using the same mask and the same etching process). At 304, the trenches 300 are filled with a dielectric material (e.g., oxide or nitride) to form barrier channels 116. The top of the substrate 102 and the barrier channels 116 may then be planarized (e.g., via polishing). Thus, the top surface of the substrate 102 and the top surfaces of the barrier channels 116 may be substantially in the same horizontal plane.

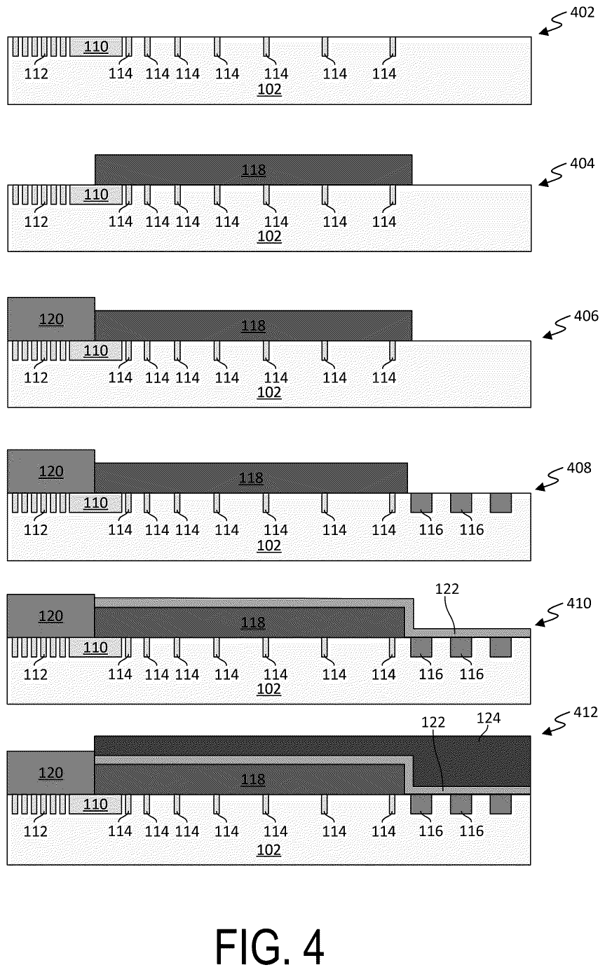

At 306, a mask is applied and then implantation (e.g., aluminum or other implantation) is performed to form implant 110, implant rings 112, and guard channels 114. At 308, the remaining layers are then formed (the formation of such layers is shown in greater detail in connection with FIG. 4). In the example depicted, these layers include the dielectric layer 118, metal layer 120, dielectric layer 122, and dielectric layer 124.

FIG. 4 illustrates an alternative flow for manufacturing barrier interfaces in a die seal region to inhibit moisture migration, in accordance with any of the examples disclosed herein. Operations depicted in FIG. 4 that are similar to operations depicted in FIG. 3 may have any suitable characteristics thereof.

At 402, a mask is applied and then implantation (e.g., aluminum or other implantation) is performed to form implant 110, implant rings 112, and guard channels 114.

At 404, dielectric layer 118 is formed by depositing a dielectric material and etching away various portions (e.g., where the metal layer 120 is to be deposited or other portions where the dielectric material is not desired). At 406, the metal layer 120 is formed (e.g., through deposition).

At 408, trenches are formed and then filled with a dielectric material to form barrier channels 116. At 410, dielectric layer 122 is formed (e.g., via deposition). At 412, dielectric layer 124 is formed (e.g., via deposition).

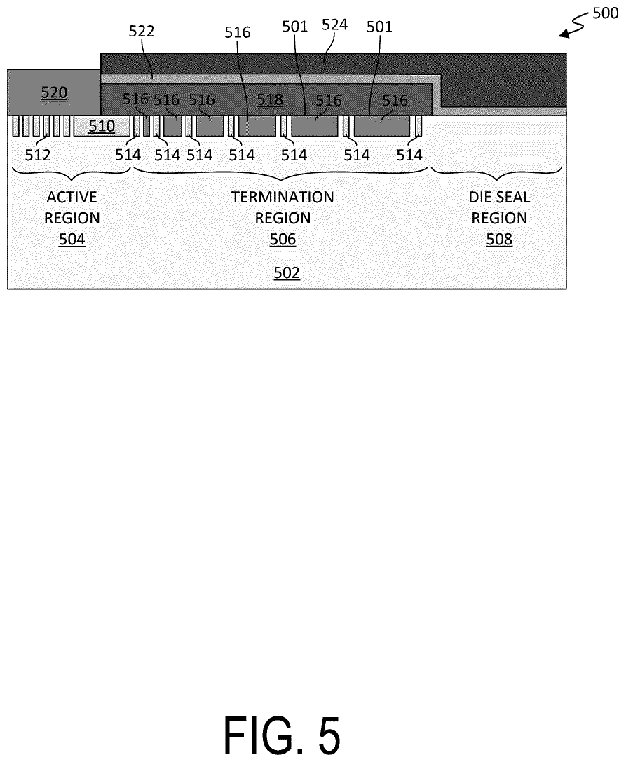

FIG. 5 illustrates a portion (e.g., an outer edge) of a die 500 comprising a semiconductor device, the die comprising barrier interfaces 501 in a termination region 506 to inhibit moisture migration, in accordance with any of the examples disclosed herein. The die 500 includes regions (active region 504, termination region 506, die seal region 508), substrate 502, implant 510, implant rings 512, guard channels 514, barrier channels 516, metal layer 520, dielectric layer 518, dielectric layer 522, and dielectric layer 524 which may respectively have any suitable features of their counterpart elements of FIGS. 1-4. For example, barrier channels 516 may include any suitable characteristics of barrier channels 116 in addition to any of the characteristics described elsewhere herein.

In this example, instead of introducing barrier interfaces inhibiting moisture propagation into the die seal region 508, the barrier interfaces 501 are formed in the termination region 506. Thus, the barrier interfaces 501 may be barrier interfaces at the locations at which the barrier channels 516 contact the dielectric layer 518. In this example, respective ones of the barrier channels 516 are positioned in between pairs of adjacent guard channels 514. In this example, the widths of the barrier channels 516 increase as the distance between the respective barrier channel 516 and the active region 504 increases. In other examples, the barrier channels 516 could have the same width (or some of the barrier channels 516 may have the same width while others have one or more different widths). Although in the example depicted adjacent pairs of barrier channels 516 are separated by a single guard channels 514, in some examples, adjacent pairs of barrier channels 516 may be separated by more than one guard channel 514.

The barrier channels 516 may have a plurality of dielectric layers formed above them. In the example depicted, the dielectric layer 518, dielectric layer 522, and dielectric layer 524 may each be formed above the barrier channels 516.

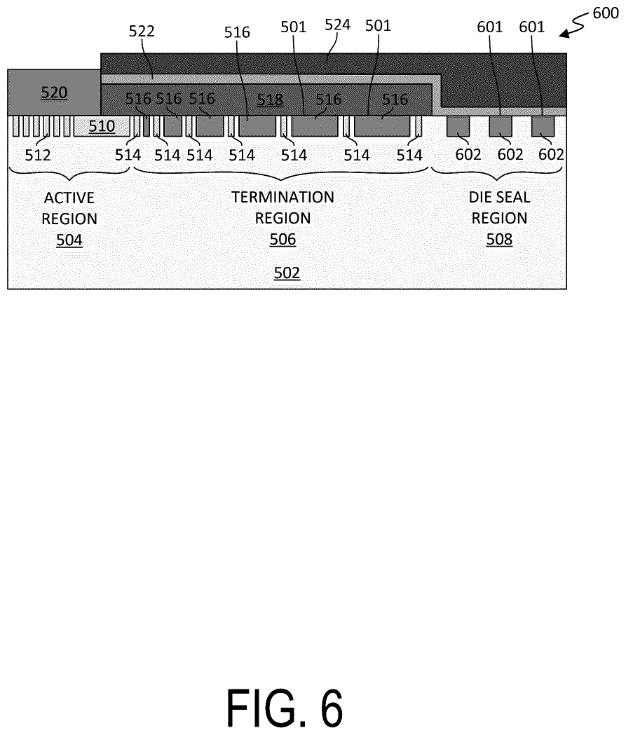

FIG. 6 illustrates a portion (e.g., an outer edge) of a die 600 comprising a semiconductor device, the die comprising barrier interfaces 601 in a die seal region 108 and barrier interfaces 501 in a termination region 506 to inhibit moisture migration, in accordance with any of the examples disclosed herein.

Die 600 is similar to die 500, except that die 600 also includes barrier channels 602 in the die seal region 508, such that the die 600 includes two different types of barrier interfaces to inhibit moisture migration. The first type of barrier interface 501 is between the barrier channels 516 and the dielectric layer 518 and the second type of barrier interface 601 is between the barrier channels 602 and the dielectric layer 522. The barrier channels 602 may include any suitable characteristics of other barrier channels described herein.

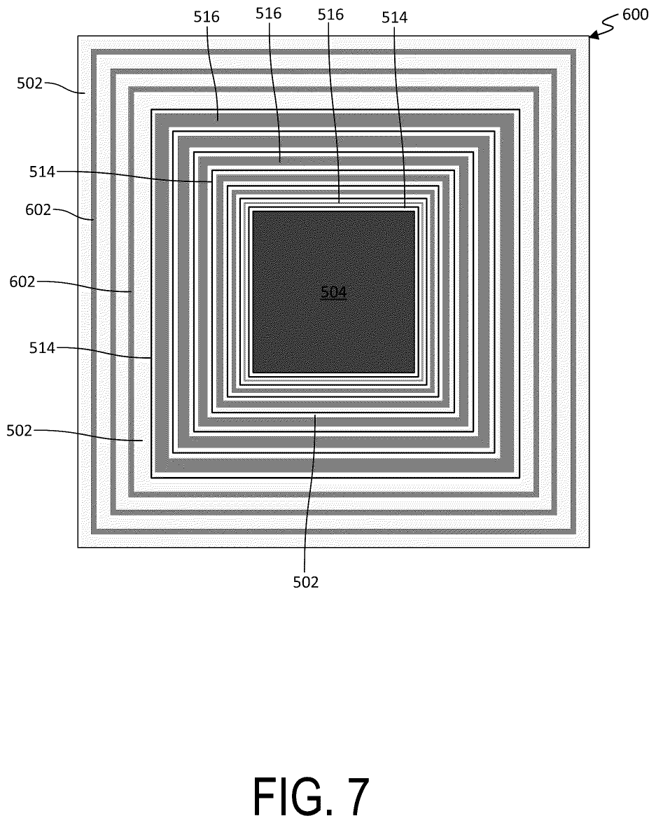

FIG. 7 illustrates a horizontal cross section of the die 600 of FIG. 6, in accordance with any of the examples disclosed herein. This horizontal cross section depicted may be through the die 600 at an elevation that passes through the guard channels 514, barrier channels 516, and barrier channels 602. As depicted, the die 600 is shaped as a square, but could have a different shape, such as substantially rectangular or other suitable shape.

In the example depicted, the center of the die 600 includes the active region 504. In this example, the guard channels 514, barrier channels 516, and barrier channels 602 comprise continuous rings around the active region 504. In this example, the rings have a generally rectangular shape, but may have other suitable shapes in other examples. In this example, the rings are concentric around the active region. For example, the guard channels 514 are concentric around the active region 504, barrier channels 516, and barrier channels 602 are concentric around the active region 504. Barrier channels 602 are concentric around the guard channels 514 and the barrier channels 516. Various barrier channels 516 are concentric around other barrier channels 516 and guard channels 514 that are closer to the active region 504.

In this example, the plurality of guard channels 514, barrier channels 516, and barrier channels 602 comprise a plurality of concentric rings, spaced at various radial distances from the active region 504. In other examples, the rings may have one or more discontinuities (but may substantially form rings). In yet other examples, the guard channels 514 or barrier channels 516 or 602 do not form rings, but are discrete channels (e.g., having a horizontal cross section of a line) near the edge of the die 600.

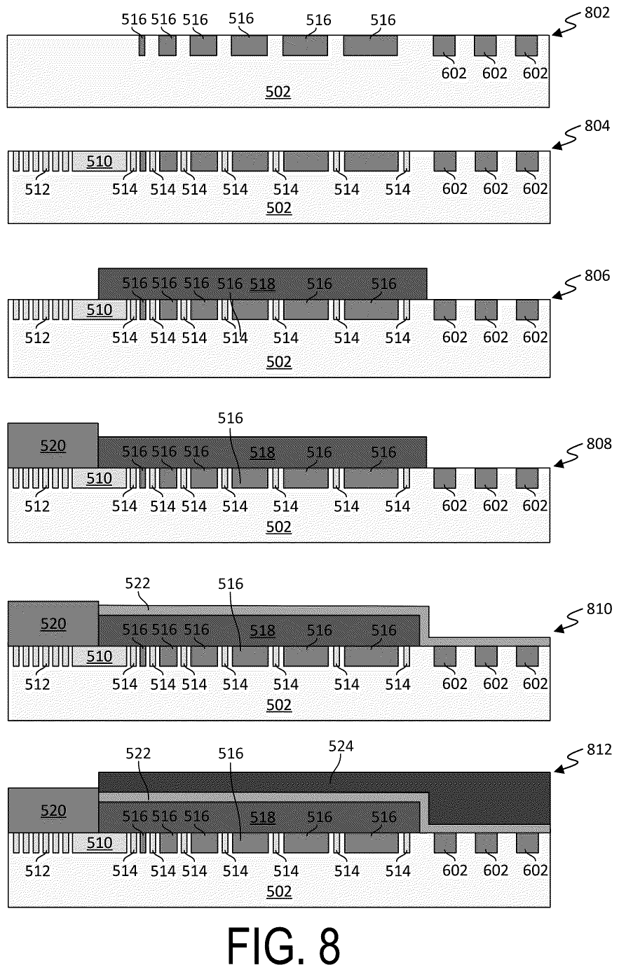

FIG. 8 illustrates a flow for manufacturing barrier channels 602 in a die seal region 508 and barrier channels 516 in a termination region 506 to inhibit moisture migration, in accordance with any of the examples disclosed herein. Operations of FIG. 8 may have any suitable characteristics of corresponding operations of the method of FIG. 4.

At 802, trenches are etched in substrate 502 and then filled with a dielectric material to form barrier channels 516 and 602. In various examples, the same dielectric material may be used for both types of barrier channels (in other examples, different dielectric materials may be used in each type of barrier channel). At 804, implantation is performed to form implant 510, implant rings 512, and guard channels 514. In an alternative flow, the implantation may be performed prior to the formation of the barrier channels 516 and 602.

At 806, dielectric layer 518 is formed and then portions of 518 are etched away. For example, the dielectric layer 518 may be formed on the barrier channels 516, guard channels 514, and substrate 502. At 808, metal layer 520 is formed. At 810, dielectric layer 522 is formed. For example, the dielectric layer 522 may be formed on the dielectric layer 518, substrate 502, and barrier channels 602. At 812, dielectric layer 524 is formed. For example, dielectric layer 524 is formed on dielectric layer 522.

The method of FIG. 8 may be adapted for manufacturing a die with barrier channels 516 within the termination region 506, but not within the die seal region 508, such as is depicted in FIG. 5. For example, the operations forming the barrier channels 602 (e.g., the forming of the trenches and the filling with the dielectric material) may be omitted.

Although particular arrangements of dielectric layers are illustrated, in other examples, any suitable dielectric layers may be formed over the substrate 102, implant 110, guard channels 114, barrier channels 116, implant 510, guard channels 514, barrier channels 516, or barrier channels 602. For example, any of these elements or portions thereof may be in contact with an oxide (e.g., a field oxide), a nitride, a polyimide, or other dielectric layer.

As used herein, the term “or” is intended to be inclusive rather than exclusive. That is, unless otherwise indicated or as would be apparent to one of skill in the art, the use of “or” is to be interpreted to mean “and/or.” For example, the phrase “A or B” is to be understood to mean “A, B, or both A and B.” The singular terms “a,” “an,” and “the” are intended to encompass their plural counterparts as well, unless it is clear from the context that a different interpretation is intended. Herein, when a list of items is preceded by phrases such as “at least one of” or “one or more of,” it is intended to allow for any combination of the listed elements.

The terms “above”, “over,” “under,” “between,” and “on,” as used herein, describe the relative positioning of components or materials. For instance, one layer being over or under another layer may encompass direct contact of the layers or the presence of one or more intermediate layers. Similarly, a layer described as being between two others may be in contact with both other layers or separated by one or more additional layers. Conversely, when a layer is “on” another layer, at least a portion of the layer is in direct physical contact with the underlying layer.

In the drawings, while some structural or method features may be shown in specific arrangements or orderings, such specific arrangements or orderings may be optional. In some examples, such features may be arranged in a different manner or order than shown in the drawings. Additionally, the inclusion of a structural or method feature in a particular drawing is not meant to imply that such feature is present in all examples, and, in some examples, such feature may not be included or may be combined with other features. Further, the various examples shown in the drawings are illustrative representations and may not be drawn to scale. In some instances, the same or similar reference numerals may be used to designate the same or similar features in different drawings.

Example 1 includes a semiconductor device comprising a substrate having a first type dopant; an active region; at least one doped channel in the substrate outside of the active region, the at least one doped channel having a second type dopant; at least one trench formed in the substrate lateral to the at least one doped channel and outside of the active region, wherein the at least one trench is filled with an oxide; and a dielectric layer on the at least one trench.

Example 2 includes the subject matter of Example 1, and wherein the semiconductor device comprises a plurality of trenches formed in the substrate, the plurality of trenches being filled with the oxide, wherein pairs of the plurality of trenches are separated by portions of the substrate.

Example 3 includes the subject matter of any of Examples 1 and 2, and wherein the oxide comprises silicon dioxide.

Example 4 includes the subject matter of any of Examples 1-3, and wherein the dielectric layer comprises oxynitride.

Example 5 includes the subject matter of any of Examples 1-4, and further including a second dielectric layer on the dielectric layer and above the at least one trench, the second dielectric layer comprising polyimide.

Example 6 includes the subject matter of any of Examples 1-5, and wherein the at least one doped channel comprises at least one ring around the active region.

Example 7 includes the subject matter of any of Examples 1-6, and wherein the at least one trench comprises at least one ring around the active region.

Example 8 includes the subject matter of any of Examples 1-7, and wherein the at least one doped channel and the at least one trench are to reduce an electric field from the active region.

Example 9 includes the subject matter of any of Examples 1-8, and further including a second trench in the substrate, wherein the second trench is laterally between two doped channels of the at least one doped channel, wherein the second trench is filled with the oxide.

Example 10 includes the subject matter of any of Examples 1-9, and further including a second dielectric layer on the second trench.

Example 11 includes a method comprising forming an active region in a substrate having a first type dopant; forming at least one doped channel in the substrate outside of the active region, the at least one doped channel having a second type dopant; forming at least one trench formed in the substrate lateral to the at least one doped channel and outside of the active region, wherein the at least one trench is filled with an oxide; and forming a dielectric layer on the at least one trench.

Example 12 includes the subject matter of Example 11, and wherein the at least one trench comprises a plurality of trenches formed in the substrate, wherein the plurality of trenches are filled with the oxide, wherein pairs of the plurality of trenches are separated by portions of the substrate.

Example 13 includes the subject matter of any of Examples 11 and 12, and wherein the oxide comprises silicon dioxide.

Example 14 includes the subject matter of any of Examples 11-13, and wherein the dielectric layer comprises oxynitride.

Example 15 includes the subject matter of any of Examples 11-14, and wherein the at least one trench comprises at least one ring around the active region.

Example 16 includes an apparatus comprising a semiconductor device package comprising a die comprising a substrate having a first type dopant; an active region; a plurality of doped channels in the substrate outside of the active region, the plurality of doped channels having a second type dopant; at least one trench formed in the substrate lateral to the plurality of doped channels, wherein the at least one trench is filled with an oxide; and a dielectric layer on the at least one trench.

Example 17 includes the subject matter of Example 16, and wherein the apparatus comprises a plurality of trenches formed in the substrate, wherein the plurality of trenches are filled with the oxide, wherein pairs of the plurality of trenches are separated by portions of the substrate.

Example 18 includes the subject matter of any of Examples 16 and 17, and wherein the at least one trench comprises at least one ring around the active region and the plurality of doped channels.

Example 19 includes the subject matter of any of Examples 16-18, and further including a printed circuit board coupled to the semiconductor device package.

Example 20 includes the subject matter of any of Examples 16-19, and further including an electrical or mechanical device coupled to the semiconductor device package through the printed circuit board.

Example 21 includes a semiconductor device comprising a substrate having a first type dopant; an active region; a termination region laterally adjacent to the active region, the termination region comprising a plurality of doped channels in the substrate, the plurality of doped channels having a second type dopant; and a trench in the substrate, wherein the trench is laterally between two of the plurality of doped channels, wherein the trench is filled with a dielectric material; and a dielectric layer on the plurality of doped channels and the trench.

Example 22 includes the subject matter of Example 21, and wherein the termination region further comprises a plurality of trenches in the substrate, the plurality of trenches filled with the dielectric material, wherein respective ones of the plurality of trenches are laterally between respective pairs of the plurality of doped channels.

Example 23 includes the subject matter of any of Examples 21 and 22, and wherein the plurality of trenches comprises a first trench and a second trench, wherein the second trench is further from the active region than the first trench, and wherein the second trench is wider than the first trench.

Example 24 includes the subject matter of any of Examples 21-23, and wherein the plurality of doped channels comprise rings around the active region.

Example 25 includes the subject matter of any of Examples 21-24, and wherein the trench filled with the dielectric material comprises a ring around the active region.

Example 26 includes the subject matter of any of Examples 21-25, and further including a second trench in the substrate, the second trench being further from the active region than a doped channel of the plurality of doped channels that is furthest from the active region, the second trench filled with the dielectric material.

Example 27 includes the subject matter of any of Examples 21-26, and further including a second dielectric layer on the second trench.

Example 28 includes the subject matter of any of Examples 21-27, and further including a plurality of second trenches in the substrate, the second trenches being further from the active region than a doped channel of the plurality of doped channels that is furthest from the active region, wherein the plurality of second trenches are filled with the dielectric material.

Example 29 includes the subject matter of any of Examples 21-28, and wherein the dielectric material comprises an oxide.

Example 30 includes the subject matter of any of Examples 21-29, and wherein the dielectric material comprises silicon dioxide.

Example 31 includes the subject matter of any of Examples 21-30, and wherein the first type dopant is n-type and the second type dopant is p-type.

Example 32 includes a method comprising forming an active region in a substrate having a first type dopant; forming a termination region laterally adjacent to the active region, the termination region comprising a plurality of doped channels in the substrate, the plurality of doped channels having a second type dopant; and a trench in the substrate, wherein the trench is laterally between two of the plurality of doped channels, wherein the trench is filled with a dielectric material; and forming a dielectric layer on the plurality of doped channels and the trench.

Example 33 includes the subject matter of Example 32, and wherein the termination region further comprises a plurality of trenches in the substrate, the plurality of trenches filled with the dielectric material, wherein respective ones of the plurality of trenches are laterally between respective pairs of the plurality of doped channels.

Example 34 includes the subject matter of any of Examples 32 and 33, and further including forming a second trench in the substrate, the second trench being further from the active region than a doped channel of the plurality of doped channels that is furthest from the active region, the second trench filled with the dielectric material.

Example 35 includes the subject matter of any of Examples 32-34, and wherein the dielectric material comprises an oxide.

Example 36 includes an apparatus comprising a semiconductor device package comprising a die comprising a substrate having a first type dopant; a plurality of doped channels in the substrate, the plurality of doped channels having a second type dopant, the plurality of doped channels to reduce an electric field from an active region of the die; a trench in the substrate, wherein the trench is laterally between two of the plurality of doped channels, wherein the trench is filled with a dielectric material; and a dielectric layer on the plurality of doped channels and the trench.

Example 37 includes the subject matter of Example 36, and further including a plurality of trenches in the substrate, the plurality of trenches filled with the dielectric material, wherein respective ones of the plurality of trenches are laterally between respective pairs of the plurality of doped channels.

Example 38 includes the subject matter of any of Examples 36 and 37, and wherein the plurality of trenches comprises a first trench and a second trench, wherein the second trench is further from the active region than the first trench, and wherein the second trench is wider than the first trench.

Example 39 includes the subject matter of any of Examples 36-38, and further including a printed circuit board coupled to the semiconductor device package.

Example 40 includes the subject matter of any of Examples 36-39, and further including an electrical or mechanical device coupled to the semiconductor device package through the printed circuit board.

While the concepts of the present disclosure are susceptible to various modifications and alternative forms, specific examples thereof have been shown in the drawings and described herein in detail. However, the concepts of the present disclosure are not limited to the particular forms disclosed, but on the contrary, all modifications, equivalents, and alternatives consistent with the present disclosure and the appended claims are also covered. Moreover, all examples described herein may be combined in any manner.

1. A semiconductor device comprising:
a substrate having a first type dopant;
an active region;
a termination region laterally adjacent to the active region, the termination region comprising:
a plurality of doped channels in the substrate, the plurality of doped channels having a second type dopant; and
a trench in the substrate, wherein the trench is laterally between two of the plurality of doped channels, wherein the trench is filled with a dielectric material; and
a dielectric layer on the plurality of doped channels and the trench.

2. The semiconductor device of claim 1, wherein the termination region further comprises a plurality of trenches in the substrate, the plurality of trenches filled with the dielectric material, wherein respective ones of the plurality of trenches are laterally between respective pairs of the plurality of doped channels.

3. The semiconductor device of claim 2, wherein the plurality of trenches comprises a first trench and a second trench, wherein the second trench is further from the active region than the first trench, and wherein the second trench is wider than the first trench.

4. The semiconductor device of claim 1, wherein the plurality of doped channels comprise rings around the active region.

5. The semiconductor device of claim 1, wherein the trench filled with the dielectric material comprises a ring around the active region.

6. The semiconductor device of claim 1, further comprising a second trench in the substrate, the second trench being further from the active region than a doped channel of the plurality of doped channels that is furthest from the active region, the second trench filled with the dielectric material.

7. The semiconductor device of claim 6, further comprising a second dielectric layer on the second trench.

8. The semiconductor device of claim 1, further comprising a plurality of second trenches in the substrate, the second trenches being further from the active region than a doped channel of the plurality of doped channels that is furthest from the active region, wherein the plurality of second trenches are filled with the dielectric material.

9. The semiconductor device of claim 1, wherein the dielectric material comprises an oxide.

10. The semiconductor device of claim 1, wherein the dielectric material comprises silicon dioxide.

11. The semiconductor device of claim 1, wherein the first type dopant is n-type and the second type dopant is p-type.

12. A method comprising:
forming an active region in a substrate having a first type dopant;
forming a termination region laterally adjacent to the active region, the termination region comprising:
a plurality of doped channels in the substrate, the plurality of doped channels having a second type dopant; and
a trench in the substrate, wherein the trench is laterally between two of the plurality of doped channels, wherein the trench is filled with a dielectric material; and
forming a dielectric layer on the plurality of doped channels and the trench.

13. The method of claim 12, wherein the termination region further comprises a plurality of trenches in the substrate, the plurality of trenches filled with the dielectric material, wherein respective ones of the plurality of trenches are laterally between respective pairs of the plurality of doped channels.

14. The method of claim 12, further comprising forming a second trench in the substrate, the second trench being further from the active region than a doped channel of the plurality of doped channels that is furthest from the active region, the second trench filled with the dielectric material.

15. The method of claim 12, wherein the dielectric material comprises an oxide.

16. An apparatus comprising:
a semiconductor device package comprising:
a die comprising:
a substrate having a first type dopant;
a plurality of doped channels in the substrate, the plurality of doped channels having a second type dopant, the plurality of doped channels to reduce an electric field from an active region of the die;
a trench in the substrate, wherein the trench is laterally between two of the plurality of doped channels, wherein the trench is filled with a dielectric material; and
a dielectric layer on the plurality of doped channels and the trench.

17. The apparatus of claim 16, further comprising a plurality of trenches in the substrate, the plurality of trenches filled with the dielectric material, wherein respective ones of the plurality of trenches are laterally between respective pairs of the plurality of doped channels.

18. The apparatus of claim 17, wherein the plurality of trenches comprises a first trench and a second trench, wherein the second trench is further from the active region than the first trench, and wherein the second trench is wider than the first trench.

19. The apparatus of claim 16, further comprising a printed circuit board coupled to the semiconductor device package.

20. The apparatus of claim 19, further comprising an electrical or mechanical device coupled to the semiconductor device package through the printed circuit board.
